(19) United States
(12) Patent Application Publication
(10) Pub. No.: US 2025/0091176 A1
(43) Pub. Date: Mar. 20, 2025

(54) CHEMICAL PLANARIZATION OF NON-METALLIC MATERIALS

(71) Applicant: CHEMPOWER CORPORATION, Beaverton, OR (US)

(72) Inventors: Sudhanshu Misra, Camas, WA (US); Suryadevara Babu, Portland, OR (US); Sriramurthy Vardhineedi, Portland, OR (US); Nikunjkumar R. Visaveliya, Lyndhurst, NJ (US)

(21) Appl. No.: 18/889,205

(22) Filed: Sep. 18, 2024

Related U.S. Application Data
(60) Provisional application No. 63/583,818, filed on Sep. 19, 2023.

(51) Int. Cl. B24B 37/24; H01L 21/768

(52) U.S. Cl. CPC B24B 37/24; H01L 21/76819; H01L 21/7684

(57) ABSTRACT

A pad for performing abrasive-free chemical planarization of a substrate comprises a polymer layer configured to contact the substrate during the abrasive-free chemical planarization. The polymer layer comprises a cerium species.

### CROSS REFERENCE TO RELATED APPLICATIONS

This application claims priority to U.S. Provisional Application 63/583,818, entitled “CHEMICAL PLANARIZATION OF NON-METALLIC MATERIALS” filed Sep. 19, 2023, the entirety of which is hereby incorporated herein by reference for all purposes.

### BACKGROUND

Chemical mechanical planarization (CMP) is commonly used in integrated circuit fabrication processes to smooth surfaces, such as that of a semiconductor substrate, by removal of material using a combination of chemical and mechanical forces. A typical CMP process involves using an abrasive and a chemical slurry that can be corrosive to the material being removed, in combination with a planarization pad. The substrate and planarization pad are pressed together, and rotated relative to one another with non-concentric axes of rotation. The combination of the force and slurry removes areas of the substrate with a higher topology compared to areas with a lower topology, thereby smoothing the surface.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to pads for performing abrasive-free chemical planarization of a substrate. One example provides a pad comprising a polymer layer configured to contact the substrate during the abrasive-free chemical planarization, wherein the polymer layer comprises a cerium species.

### BRIEF DESCRIPTION OF THE FIGURES

FIG. 1 shows a block diagram of an example chemical planarization system.

FIG. 2A shows a schematic depiction of an example pad for performing chemical planarization.

FIG. 2B shows the example pad of FIG. 2A and illustrates contact between topologically higher portions of a substrate and an upper layer of the pad.

FIG. 3 shows a schematic depiction of another example pad for performing chemical planarization.

FIG. 4 shows a schematic depiction of another example pad comprising a textured substrate-facing surface.

FIG. 5 schematically illustrates examples of incorporation of a cerium species and optionally a functional group into a polymer.

FIG. 6 illustrates examples of monomers that can be used to form a pad for chemical planarization.

FIGS. 7A-7B show a flow diagram depicting an example method of forming a pad for chemical planarization.

FIG. 8 shows a schematic depiction of another example pad for performing chemical planarization.

FIG. 9 schematically illustrates an example of complexing of a cerium species by a polymer.

### DETAILED DESCRIPTION

As the complexity of semiconductor devices, such as logic, memory, and other devices, continues to increase along with a decrease in feature sizes, various integration schemes have been utilized for device interconnections. Some such integration schemes involve a mix of metal and non-metallic films to form conducting multilayer interconnect wiring separated by electrically insulating layers. These structures require nanolevel planarization for the multilevel wiring structures to be completed.

CMP can be used to planarize these interconnect structures. For example, oxide films of silicon can be polished using dispersions of cerium oxide abrasives, and/or particles of cerium oxide embedded in a planarization pad. In some examples, one or more additives can be added to a dispersion of cerium oxide to control polish rates, rate selectivity compared to the rates of the underlying films, and other performance characteristics.

While current methods of CMP find use in a wide variety of device fabrication contexts, current CMP methods also pose various drawbacks. For example, current CMP processes are relatively dirty compared to other fabrication processes, due at least in part to the use of conditioner chemicals, as well as the abrasive slurry and pad that mechanically abrade the material during planarization. Defects generated by CMP can be large yield loss contributors to fabs. Defects and scratches generated during CMP may largely originate from the mechanical components in the process, such as the abrasives in the slurry, the force of the pad against the substrate, pad conditioning, and tribological aspects of the process. Further, the slurry contains abrasives that can scratch device layers, thereby creating pits and leaving residues that can become killer defects. Smaller technology nodes are more susceptible to such defects, which can reduce yields of logic, memory, and other semiconductor devices.

Additionally, pad debris is generated during polish and pad conditioning. Such pad debris can create particles and agglomerates that contaminate the substrate being processed. For example, cerium oxide or other particles embedded in the pad can come loose and cause scratches or other defects. Also, the force of the pad against the wafer can cause pad deformation. This can result in shear stresses at interfaces from intimate contact with the substrate and relative motion between the substrate and pad. Further, CMP processes may not be predictable, and thus may be dominated by trial-and-error approaches, rather than analytical approaches. Further still, the handling, delivering and stabilization of slurries can pose difficulties for fabrication facilities due to solid content. This can increase facilities maintenance costs. Any abrasive in the aqueous media or such species that gets detached from the pad and released into the aqueous media can cause scratches and defects and would limit planarization and result in a lower planarization efficiency, the relative removal of the high topography areas compared to the low areas. Such lowering of planarization efficiency, as in conventional CMP processes can require redundancy in deposition and overplanarizing, which can lead to wasted resources, increased costs, and lower productivity.

Accordingly, examples are disclosed herein that relate to pads for performing planarization chemically that eliminate the need for abrasive particles during planarization, and without the dirty and defect-prone mechanical processes used in conventional CMP methods.

Briefly, the disclosed examples utilize an abrasive-free planarization chemistry at a pad instead of an abrasive slurry. The term “abrasive-free” indicates a planarization chemistry without a mechanically abrasive solid component for removing substrate material by abrasion. The disclosed pads comprise at least one polymer layer configured to contact the substrate during the abrasive-free chemical planarization. The polymer layer comprises a cerium species. The cerium species allows the disclosed pads to remove non-metallic materials from a substrate surface. The term “cerium species” generally refers to a cerium (III) and/or a cerium (IV) ion contained within the pad, as opposed to abrasive cerium oxide particles. The cerium species can be freely dispersed within the pad (e.g. as a salt), or complexed or ionically or covalently bonded to functional groups of the polymers of the pad.

Using the disclosed pads, the substrate can be controlled to contact topologically higher features of the substrate to the pad, and not contact topologically lower features of the substrate. Planarization chemistry is exposed to portions of the substrate in contact with the pad, while the low-lying areas are protected, thereby selectively removing material from those portions of the substrate. In this manner, the topology of the substrate surface may be made smoother without using abrasives, and by applying relatively light pressure against the substrate. This may help to avoid scratching or otherwise damaging the device layer, thereby helping to avoid defects and potentially improving yields over conventional CMP processes.

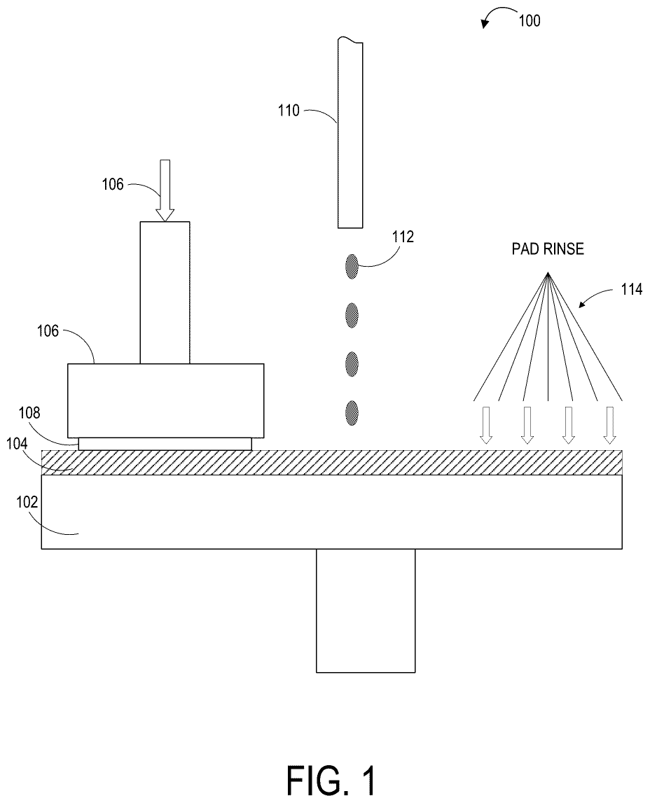

Prior to discussing the disclosed examples of abrasive-free planarization pads, FIG. 1 shows a schematic depiction of an example chemical planarization system 100 according to the present disclosure. System 100 comprises a platen 102 that supports a pad 104. The system 100 further includes a substrate holder 106 configured to hold a substrate 108 against the surface of the pad 104, and a planarization solution introduction system 110 for introducing a planarization solution 112 onto the pad 104. The system 100 further may comprise a pad rinsing system 114 configured to rinse possible contaminant materials from the pad 104, such as complexed materials that have been removed from the surface of the substrate 108. Pad rinsing system 114 also may be used to clean the pad between using different planarization solution chemistries, as described below. Other components (not shown) that may be incorporated into system 100 include, but are not limited to, a spent solution recovery system, a materials recirculation system (e.g. for recirculating the planarization solution in a closed loop process), and a species stripping system.

In conventional CMP processes, the substrate holder pushes the substrate against a planarization pad supported on a platen, and the pad and the substrate are rotated relative to one another in a non-concentric pattern. In such conventional processes, relatively high rates of rotations are used, such as between 40-100 rpm. Further, the substrate is pushed against the pad with a relatively high pressure, such as in a range of 1-4 pound per square inch. In contrast, a lighter pressure can be used in the disclosed examples, including but not limited to pressures in the range of 0.25 to 0.75 pounds per square inch. The lighter pressure may avoid distortion of the pad shape, and may reduce shear stresses compared to conventional CMP processes. Likewise, a slower rate of rotation may be used in the disclosed examples than with conventional CMP processes, as the rotational motion is not used for abrasion. Instead, rotation of the platen 102 helps to distribute planarization fluid across the pad 104. Any suitable rate of rotation may be used. Examples include rates in a range of 0-100 rpm. More specific examples include rates of 5-60 rpm. As mentioned above, the rate of rotation may be lower than a rate at which a platen rotates in a conventional CMP process, as the rotational motion is not being used in the examples herein to abrade material from a substrate. It will be understood that many different configurations and designs are possible for a variety of platform types (rotary, linear or belt style, vertically, rollers, hollow fibers).

The planarization solution may comprise chemical components to hydrolyze a substrate material (e.g. by oxidation and dissolution). The planarization solution may be configured to remove any suitable materials. As one example, polysilicon may be removed via a planarization solution comprising poly(diallyldimethylammonium chloride) (PDADMAC) in deionized water. In some such examples, the PDADMAC solution may be mixed with oxalic acid and/or hydrogen peroxide, and further may comprise a suitable acid or alkaline agent (e.g. nitric acid or potassium hydroxide) to adjust the pH. Other reagents also may be used to planarize polysilicon, including but not limited to poly(2-acrylamido-2-methyl-1-propanesulfonic acid) (polyAMPS), poly(dimethylamine-co-epichlorohydrin-co-ethylenediamine), poly(allylamine), and poly(ethylene imine) (PEI). In other examples, one or more metals such as copper, molybdenum, ruthenium, rhenium, rhodium, and cobalt, as examples, may be removed using a planarization solution comprising hydrogen peroxide and guanidine carbonate, again with pH adjusters to achieve a desired solution pH. As another example, ammonium persulfate may be used for removal of suitable metals (e.g. cobalt), with pH adjusters to achieve a desired solution pH. Other examples of suitable hydrolyzing agents may include, but are not limited to, nitric acid, sulfuric acid, hydrochloric acid, phosphoric acid, ammonium hydroxide, sodium hydroxide, and potassium hydroxide. In some examples, the planarization solution additionally or alternatively comprises a cerium species (e.g., Ce(III) or Ce(IV)) configured to remove non-metal substrate materials, such as polysilicon, silicon nitride, silicon carbonitride, silicon oxide, silicon oxycarbide, and silicon oxynitride.

In some examples, the planarization solution may comprise additional components. For example, the planarization solution may comprise complexing/chelating agents to transport removed material from the substrate after hydrolysis. Examples of suitable chelating agents may include, but are not limited to, ethylenediaminetetraacetic acid (EDTA), sulfosalicylic acid, napthol (PAN), dithizone, organophosphorus acid esters, polyethylene glycol, amines, and thioxine. Further, in some examples, the planarization solution may comprise passivating agents and/or corrosion inhibitors. Examples include, but are not limited to, benzatriazoles (BTA), ammonium dodecyl sulfate (ADS), tolyltriazoles (TTA), thiols (e.g. PTAT (5-(phenyl)-4H-1,2-4-triazole-3-thiol)), thiodiazoles, carboxylic acids, benzoic acid, and ammonium benzoate. Other examples of materials that may be included in the planarization solution include, but are not limited to, surfactants, surface modifiers other than passivation and/or corrosion inhibitors, catalysts, thermally activated chemicals, light activated chemicals, species tracers, additives, and stabilizers.

Inhibitors such as BTA can help to achieve planarization by suppressing removal rates at low topography areas of a wafer, especially with metallic films. However, BTA and other corrosion inhibitors can be hazardous and may also pose environmental challenges during disposal. Furthermore, BTA may complicate the process of cleaning wafers after planarization, as it can interact with other substances (e.g., nano-abrasives) in conventional CMP processes to create residues on the wafers that are difficult to remove. As described in more detail below, functionalized pads comprising a cerium species can selectively planarize high topography areas without the use of added inhibitors. This results in a cleaner process and obviates additional post-planarization cleaning steps.

In some examples, hydrolyzing agents and complexing agents are bonded to functionalized polymers of the pad, as described in more detail below. The hydrolyzing and complexing agents may form complexes with cerium species incorporated within the pad. In some such examples, the planarization solution dispensed onto the pad may include deionized water, and the chemical planarization may be performed by the cerium species and optionally the functionalized polymers, depending upon a material being planarized. In other such examples, the planarization solution may include additional components other than deionized water.

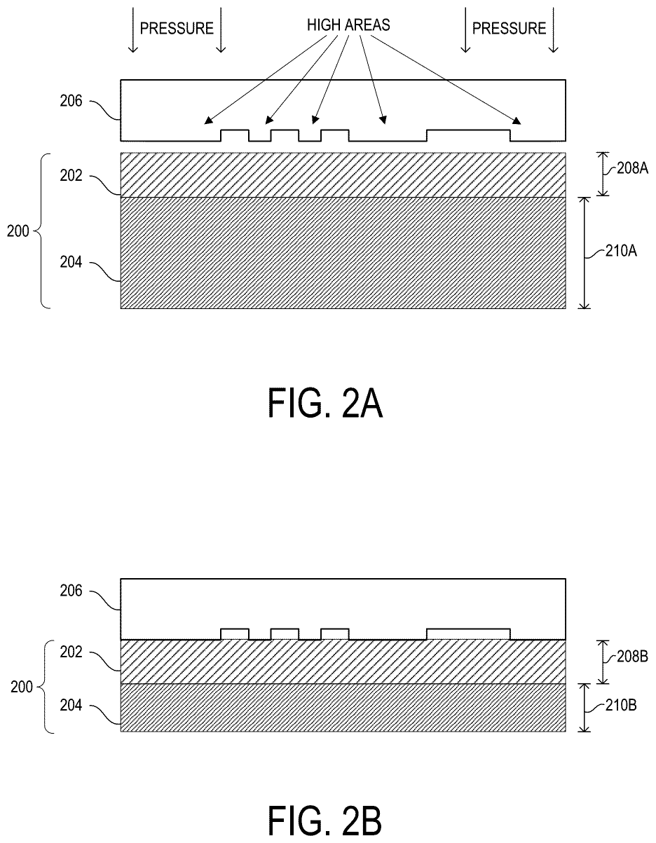

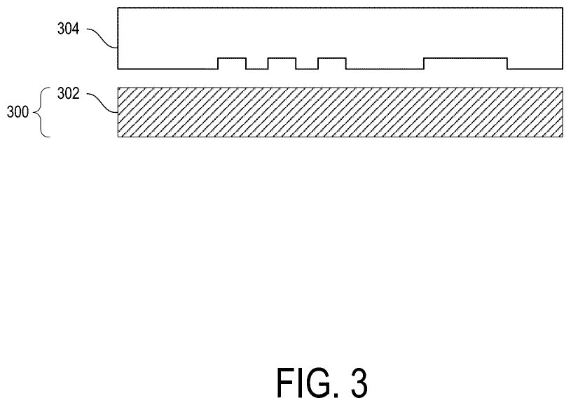

FIGS. 2A-2B show a schematic view of an example pad 200 that is suitable for use as pad 104. The pad 200 includes a first polymer layer 202 and a second polymer layer 204. The first polymer layer 202 is configured to contact substrate 206 during abrasive-free chemical planarization. The second polymer layer 204 is positioned on an opposite side of the first polymer layer 202 as a substrate-contacting side of the first polymer layer 202. Such a dual layer structure may be used to implement a multi-sequence material removal and separation process, wherein the steps comprise one or more chemical steps—hydrolysis (and potential dissolution) of the species being removed, oxidation, hydroxylation, ionization, radical formation, and/or chemical complexation of the species being removed, based upon a chemical formulation of the pad and a composition of the planarization solution. Further, the first polymer layer 202 and the second polymer layer 204 can be configured to have other functionalities. For example, the second polymer layer can be configured to be compressible. As such, when the first polymer layer 202 is brought into contact with substrate 206 during a chemical planarization process, the second polymer layer 204 can compress to avoid applying unwanted pressure against the substrate 206. Further, the first polymer layer can comprise a textured surface in some examples, as described in more detail below.

The first layer and second layer may be joined together in any suitable manner. In some examples, the first layer and the second layer are joined by an adhesive. In other examples, one of the first layer or second layer is insert molded into the other of the first layer or the second layer. In yet other examples, one or both of the first layer or the second layer can be additively manufactured. In yet further examples, the first layer and the second layer can be formed in a same molding or casting process, but wherein the composition of the material being molded or cast is changed mid-pour or mid-injection. In such examples, by virtue of having dissimilar characteristics between the top layer and the bottom layer, this constitutes an asymmetric medium. Such an asymmetric medium may, in some examples, include a gradual and systematic variation in characteristics, or may transition abruptly at the interface of two layers. This enables control over compressibility and other mechanical characteristics of the first polymer layer 202 and/or the second polymer layer 204. In other examples, the two layers will be integrated and seemingly compose a composite pad. Furthermore, the pad 200 may be adhered or otherwise joined to an additional sub-layer, such as a woven textile matrix or soft polymer sheet (e.g. sub-pads of the type currently used for conventional CMP pads).

In some examples, polymer phase inversion or phase separation may be used to form such an asymmetric structure. In other examples, vapor induced phase separation (air casting) may be used. As yet another example, liquid induced phase separation (immersion casting) may be used by dissolving polymer in solvent at room temperature and immersing in liquid non-solvent to induce phase separation. This enables different morphologies including asymmetric membranes. Methods for forming an asymmetrical structure (e.g. a multi-layer porous matrix) include manipulating phase separation conditions during single layer casting, casting a small pore size membrane on a large pore size substrate, casting multi-layers of different pore sizes contemporaneously, laminating different pore size layers together, and utilizing temperature induced phase separation (TIPS or melt casting) (in which a polymer is heated above melting point and dissolved in porogens, and phase separation induced by cooling).

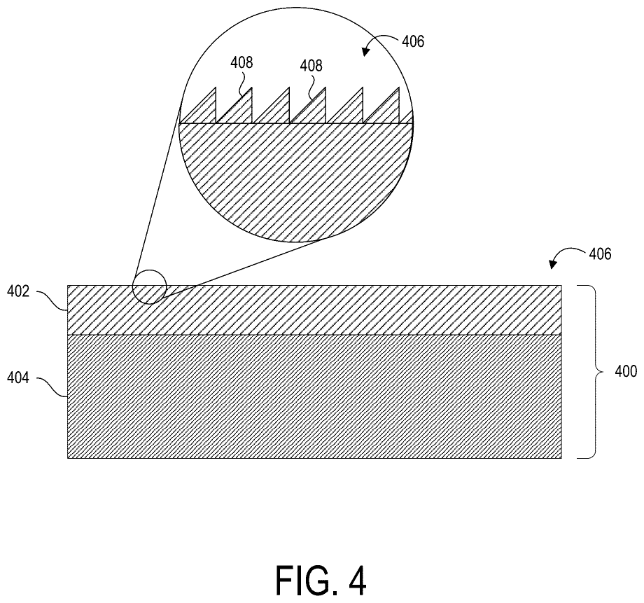

In other examples, the pad comprises a single polymer layer. FIG. 3 shows a schematic view of another example pad 300 that is suitable for use as the pad 104 of FIG. 1. The pad 300 comprises a single polymer layer 302 configured to contact substrate 306. In some such examples, both hydrolysis and/or complexation of the cerium species and subsequent chemical planarization are configured to occur in a same layer. In yet other examples, a pad comprises three or more layers.

Referring again to FIGS. 2A-2B, in some examples, the first polymer layer 202 may be relatively thin compared to the second pad, and may be configured for hydrolysis and/or complexation of a material being planarized. As such, the first polymer layer 202 may comprise relatively larger pores, may be hydrophilic, and may be surface modified to functionalize the polymer surface, thereby allowing the polymer of the first polymer layer 202 to participate in hydrolysis reactions. The first layer also comprises a cerium species to facilitate planarization of such materials as silicon oxide. In some such examples, the first layer may have a thickness in a range of 0.1 micron to five microns thick. In other examples, the first layer can have any other suitable thickness (e.g., a thickness of less than 0.1 microns or greater than five microns). In yet other examples, the first polymer layer 202 can be nonporous. For example, and as described in more detail below, the first polymer layer may comprise a textured surface that provides additional surface area for the abrasive-free planarization chemistry.

In some examples, the second polymer layer 204 may be relatively thicker than the first layer, and may have relatively smaller pores than the first layer. In some examples, the second layer may be configured to retain materials removed by the first layer. For example, the second layer may comprise a surface that is chemically modified with complexing agents adsorbed or bonded to the second layer within the pores to retain material removed from the substrate. In some examples, the second layer may have a thickness of several microns to 3 mm thick, and in more specific examples, from 40 microns to 2 mm thick.

FIGS. 2A-2B also depict contact between a substrate 206 and the pad 200. As shown in FIGS. 2A-2B, topologically higher regions of the substrate 206 contact the pad 200, and the pad 200 does not contact topologically lower regions of the substrate. The use of relatively little pressure of the substrate 206 against the pad 200, combined with the planarization chemistry being located within the pad 200 instead of in the space between the pad and substrate, helps to achieve removal of material from the topologically higher regions of the substrate 206 at a higher rate compared to, or even to the exclusion of, the topologically lower regions, as the topologically higher regions are in contact with the hydrolyzing and/or complexing environment in the pad.

In FIGS. 2A-2B, pressure is applied via the substrate 206 that presses the substrate 206 against the pad 200. In some examples, the pad 200 is compressed merely by a weight of the substrate 206. In other examples, additional force is applied to the substrate 206 (e.g., via the substrate holder 106 of FIG. 1) to press the substrate 206 against the pad 200. Such force(s) can cause compression of the pad 200 as shown in FIG. 2B. In some examples, as introduced above, the second polymer layer 204 is configured to provide compressibility while the first polymer layer 202 can have a porous and/or textured surface configured to remove material during the abrasive-free chemical planarization process.

Further, the first and/or second layer may be designed with mechanical attributes such that it is rigid enough to handle the wafer load and the down force/applied pressures. In some examples, the first polymer layer and/or a second polymer layer may have a storage modulus of 15 MPa to 1200 MPa. More specific examples include storage moduli of 400-800 MPa. In some examples, the first polymer layer and/or the second polymer layer have a loss modulus of 100-600 MPa. More specific examples include loss moduli of 150-500 MPa. In some examples, the first polymer layer and/or a second polymer layer have a Tan delta (loss divided by storage) of 0.2-0.9. More specific examples include 0.4-0.8. In some examples, the first polymer layer and/or a second polymer layer have a compressibility of <5%, and/or a surface tension of less than 40 mN/m. The viscoelastic characteristics and physical attributes of the first polymer layer and/or the second polymer layer can be determined by standard dynamic mechanical analysis (DMA), differential scanning calorimetry (DSC) and thermogravimetric analysis (TGA) methods, as examples.

In some examples, as mentioned above, the second polymer layer 204 is more compressible than the first polymer layer 202. The first layer polymer 202 has a thickness 208A in FIG. 2A before compression. The first polymer layer 202 has a second thickness 208B after compression that is substantially the same as the first thickness 208A. In contrast, the second polymer layer 204 has a first thickness 210A before compression. The second polymer layer 204 has a second thickness 210B in FIG. 2B that is less than the first thickness 210A of FIG. 2A. In this manner, the second polymer layer 204 may absorb compressive force while the first polymer layer 202 maintains a planar substrate-facing surface. In other examples, the first polymer layer 202 is more compressible than the second polymer layer 204. In this manner, the second polymer layer 204 can serve as a relatively firm “bed” that supports the first polymer layer 202 against the substrate 206.

The first and second layers may comprise any suitable material or materials. In some examples, the first polymer layer 202 and/or the second polymer layer 204 may comprise one or more of polyurethane, polyanhydride, polycarbonate, polyacrylate, polysulfone, polyester, polyacrylonitrile, polyethersulfone, polyarylsulfone, polyacrylonitrile, epoxy, or polyvinylidene fluoride. Further, in some examples, the first layer and/or the second layer may have a 60-90 shore A hardness or 30-60 shore D hardness. In other examples, the first layer and/or second layer may have hardness values outside of these ranges. All ranges stated herein are inclusive of endpoint values.

In some examples, the first layer comprises a thermoplastic material and the second layer comprises a thermoset material. In some such examples, the second polymer layer 204 can be formed from a thermoset polymer with more crosslinking than the first polymer layer 202. As described in more detail below, the thermoplastic material can be 3D-printed on the second polymer layer 204 or otherwise formed in a more controlled manner than casting or injection molding. This enables fine control over the structure and physical characteristics of the pad. In further examples, both the first layer and the second layer can be formed from a thermoset material, or both layers can be formed from a thermoplastic material.

As mentioned above, the first layer and/or the second layer can optionally comprise a porous polymer. In some examples, pores are formed in the first layer and/or the second layer utilizing TIPS or melt casting. Other techniques to form pores within the polymer include introducing a blowing agent such as steam and/or other gases (e.g., air, carbon dioxide, or nitrogen) to form bubbles in the molten polymer before it solidifies.

In some more specific examples, the first polymer layer 202 has a smaller pore fraction than the second polymer layer 204. For example, the first layer may have an average pore size in a range of 1 nm to 1000 nm, preferably 30 nm to 200 nm. The second layer may also have an average pore size in a range of 5 nm to 1000 nm, preferably 200 nm to 1000 nm. In such examples, the second polymer layer 204 can provide suitable compressibility to accommodate deformation of the first polymer layer 202. In other examples, the first polymer layer 202 has a greater pore fraction than the second polymer layer 204. In yet other examples, one or more of the first polymer layer 202 and/or the second polymer layer 204 is nonporous.

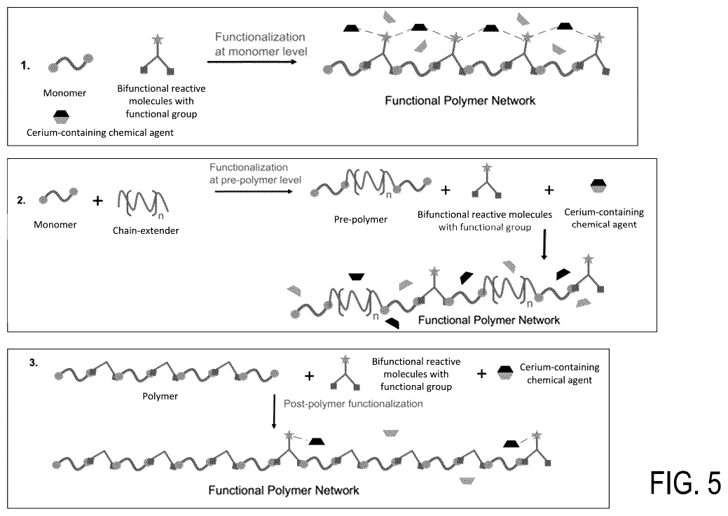

In some examples, the first layer comprises a textured substrate-facing surface. FIG. 4 shows show a schematic view of another example pad 400 that is suitable for use as the pad 104 of FIG. 1. The pad 400 includes a first polymer layer 402 and a second polymer layer 404. The first polymer layer 402 comprises a textured substrate-facing surface 406 configured to contact a substrate during abrasive-free chemical planarization. The textured substrate-facing surface 406 comprises a plurality of structures 408, such as bumps, ridges, or grooves, that can cause friction between the pad 400 and the substrate, which can lead to the removal of material from the substrate. In addition, the textured surface can compensate for a lack of porosity by providing surface area for chemical reactions and/or channels that conduct planarization fluid during processing.

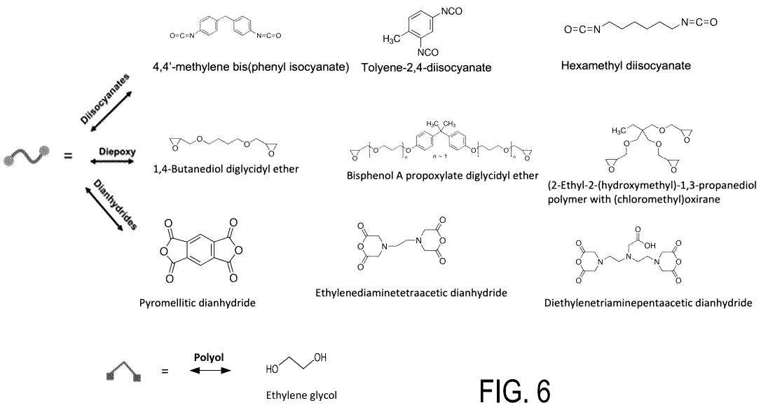

As described in more detail below with reference to FIG. 5, the first polymer layer and/or the second polymer layer comprise a plurality of reactive units covalently bonded within polymer chains. Each reactive unit comprises a functional group. In some examples, the functional groups of the reactive units can act as a chelating and/or coordinating ligands for cerium species (Ce(III) and/or Ce(IV) ions). In other examples, cerium species can ionically or covalently bond to the functional groups, or be or freely dispersed within the first polymer layer and/or the second polymer layer. FIG. 5 schematically illustrates incorporation of the functional group into the polymer, and also the incorporation of a cerium species into the polymer. In some examples, the functional group comprises a hydrolysis and/or a complexation agent for incorporating the cerium species into the polymer. In some examples, the functional groups comprise one or more of a carboxylic acid, an amine, a sulfonic acid, an alcohol, a phosphonic acid, an amide, a sulfate, a nitrate, and/or a polyethylene. In some more specific examples, the functional groups comprise one or more of iminodisuccinic acid, ethylenediaminedisuccinic acid, glutamic acid, methylglycinediacetic acid, dicyanamide, polyAMPS, or polydiallyldimethylammonium chloride. Such species can also be used as chelating agents separate from a pad, in addition to or alternatively to the functionalization of a pad with such species. In other examples, any other suitable functionalization may be performed to impart any desired chemical functionality to the pad. For example, the functionalization may be optimized to form a complex (e.g. a chelate and/or coordination complex) with a cerium species, thereby incorporating the cerium species into the pad. In other examples, the cerium species may be ionically or covalently bonded to the functional group. Other examples of functional groups include, but are not limited to, —COOCH₂CH₂OH, —N(CH₂CH₂OH)₂, and —CONHR. In further examples, the cerium species may be freely dispersed within the polymer layer.

In some examples, the polymer layer comprises a hybrid of a covalently bonded functional group and a distribution of functional groups freely dispersed in the polymer matrix. As mentioned above, the functional groups can be bonded to cerium species. The cerium species can form complexes with the functional groups, can be ionically or covalently bonded to the functional groups, or can be freely dispersed within the polymer layer. In this manner, dispersed functional groups and cerium species can be released upon contact with a planarization solution to assist in planarization. For example, oxalic acid can be dissolved into a polymer blend during pad manufacturing so that it can be released into planarization media during planarization. The two —COO groups from oxalic acid assist in Cu complexation enhancing the removal of Cu. Likewise, free oxalic acid also can complex cerium species to help disperse the cerium species within the pad, and to assist in the planarization of silicon oxide and other species that can be planarized using cerium species. In this manner, a functionalized pad comprising a cerium species may enhance material removal rates. Furthermore, a process can be operated repeatedly without reconditioning the pad since abrasives are not used, as long as the dispersed species is not limiting and the pad surface asperities maintain integrity upon multiple planarization cycles. In the event a conditioning process is used to mechanically abrade the pad, the planarization process will remain abrasive-free. In some such approaches where abrasive conditioning is implemented, the pad may include surface grooves or channels to facilitate removal of polymer debris during conditioning. Since there are no abrasives, the advantage still holds for a low-defect planarization process. The environmental benefits are valid during the planarization process as the effluent can be chemically treated for species and water recovery. Polymer residues from abrasive conditioning may be separated prior to any environmental disposal.

Any suitable method may be used to incorporate a cerium species and optionally a functional group into a planarization pad. In some examples, a polymer of the planarization pad can be functionalized during polymer synthesis. FIG. 5 schematically illustrates incorporation of the cerium species and optionally the functional group into the polymer. In scheme (1), a monomer is linked to a chemical agent comprising a cerium species and optionally a bifunctional reactive molecule that contains a target functional group. The cerium-containing chemical agent, such as a cerium salt, may be incorporated during polymerization to provide the cerium species. Polymerization results in distribution of the cerium species and the target functional group throughout the polymer (including within a solid mass of the polymer). For example, in scheme (1), the cerium species (black trapezoid) of the cerium-containing chemical agent is bonded to the functional group of the bifunctional reactive molecule within the functional polymer network, represented by dashed lines. In this example, the counterion (gray trapezoid) of the cerium-containing chemical agent is freely dispersed within the functional polymer network. In this manner, the cerium species and functional groups are incorporated homogeneously throughout the polymer layer.

In some examples, the target functional group may act as a complexing ligand for the cerium species. In other examples, the cerium species may be ionically or covalently bonded to the functional group, or freely dispersed within the polymer. Example cerium salts that can be used to incorporate cerium species into a pad include cerium trichloride, cerium sulfate, cerium nitrate hexahydrate, cerium carbonate, cerium acetate, cerium ammonium nitrate, cerium(III) methanesulfonate (Ce(CH₃SO₃)₃), cerium(III) trifluoromethanesulfonate (Ce(CF₃SO₃)₃), and combinations thereof.

One potential advantage of this approach is the presence of cerium species and optionally functional groups at pore surfaces throughout the pad. Furthermore, mechanical wear and/or chemical degradation reveals additional cerium species and optionally functional groups below the substrate-facing surface, enabling the pad to operate longer than a pad lacking interior cerium species and optionally functional groups. In addition, a single layer pad may be manufactured in a single step, thereby decreasing manufacturing time and costs relative to a pad having two or more layers.

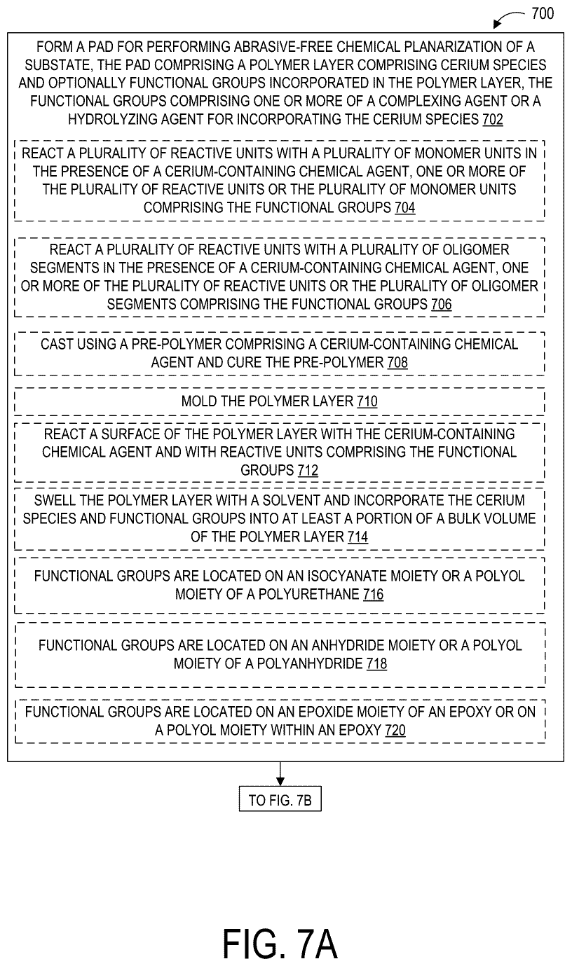

Monomers that are suitable for generating a cross-linked polymer network with curing agents, cerium species, or optionally functionalized reactive molecules include monomers which possess at least two reactive sites. As illustrated by way of example in FIG. 6, some examples of suitable monomers include diisocyanates (e.g., 4,4′-methylene bis(phenyl isocyanate), tolyene-2,4-diisocyanate, and hexamethyl diisocyanate), diepoxies (e.g., 1,4-butanediol diglycidyl ether, bisphenol A propoxylate diglycidyl ether, and (2-ethyl-2(hydroxymethyl))-1,3-propanediol polymer with (chloromethyl)oxirane), and anhydrides (e.g., pyromellitic dianhydride, ethylenediaminetetraacetic dianhydride, and diethylenetriaminepentaacetic dianhydride). In some examples, such monomers react with ethylene glycol and/or substituted forms of ethylene glycol (e.g., glyceric acid) to form a polyurethane that contains un-reacted carboxylic acid groups. These carboxylic acids can serve as chelating ligands for the incorporation of cerium species within the polymer layer.

In some examples, the polymer layer comprises a polyurethane. In some such examples, the functional groups are located on an isocyanate moiety of the polyurethane. Reaction of a hydroxyl group or an amine group with the isocyanate can create the urethane linkage of the polymer backbone. Some examples of suitable molecules that can react with diisocyanate monomers include polyols (e.g., glyceric acid). In some such examples, the functional groups are located on a polyol moiety of the polyurethane. Other examples of suitable molecules that can react with diisocyanate monomers include 2-2′-bis(hydroxymethyl)propionic acid and 3,4-dihydroxybenzoic acid. In some such examples, an acid moiety can serve as a chelating or coordinating ligand, or otherwise an ionic bonding site, for the incorporation of cerium species within the polymer layer. In other examples, the cerium species can be freely dispersed within the polymer layer.

In other examples, the polymer layer comprises a polyanhydride. In some such examples, the functional groups are located on an anhydride moiety of the polyanhydride. The functional groups can form complexes with the cerium species or can be ionically or covalently bonded to the cerium species. The cerium species can also be freely dispersed within the polymer layer. Polyanhydrides can be formed by condensation between two carboxylic acid groups, resulting in the elimination of a water molecule. The anhydride moieties renders polyanhydrides more reactive and more prone to hydrolysis than other polymers (e.g., polyurethane). This can result in a biodegradable polymer network that reduces environmental impact of waste materials. In some such examples, the polyanhydride further comprises polyol moieties covalently linked with the polyanhydride. In some such examples, the functional groups are additionally or alternatively located on the polyol moieties. As mentioned above, the functional groups can form complexes with the cerium species or can be ionically or covalently bonded to the cerium species. The cerium species can also be freely dispersed within the polymer layer. Polyols can be incorporated into polyanhydride-based systems as additives or modifiers. For example, polyols can be used as plasticizers to increase flexibility of the polyanhydride. Polyols can also be employed as components in copolymers, such as a copolymer including a polyanhydride linkage and a polyester linkage. This can result in a hybrid material with customized properties (e.g., flexibility and compressibility) tuned for chemical planarization.

In other examples, the functional polymer network is additionally or alternatively formed using a curing agent and/or a cross-linking agent that contains the target functional group. The functional groups can form complexes with the cerium species or can be ionically or covalently bonded to the cerium species. In yet other examples, functional polymers are cross-linked with a cross-linking agent that does not contain the target functional group. In these examples, the cerium species can also be freely dispersed within the polymer layer. Cross-linking results in a three-dimensional polymer network that is stronger and more rigid than unlinked polymers.

In some such examples, the polymer layer comprises an epoxy. The epoxy can be formed treating precursor molecules comprising epoxide functional groups with a curing agent. The curing agent causes crosslinking of the precursor molecules to form a three-dimensional network structure. In some such examples, the functional groups are located on an epoxide moiety of the epoxy. In other examples, the functional groups are additionally or alternatively located on a curing agent and/or a polyol bound within an epoxy chain. As described above, polyols can be incorporated into a polymer layer to tailor one or more properties of the polymer, such as flexibility and toughness, viscosity, adhesion, and hydrophobicity. In some examples, addition of a polyol or other additive can change the rate or extent of cross-linking, which can also be used to tailor the properties of the polymer.

Referring again to FIG. 5, in some examples, the functional groups are separated by oligomeric segments of the polymer chain. For example, in scheme (2), the monomer is linked to a chain extender to form an extended pre-polymer molecule. In this example, a cerium-containing chemical agent can be mixed with the extended pre-polymer molecule. The extended pre-polymer molecule is then polymerized in the presence of a bifunctional reactive molecule containing the target functional group to form a functional polymer network that incorporates the cerium species, as shown in FIG. 5. In some examples, the cerium species provided by the cerium-containing chemical agent can form a complex (e.g. a chelation or coordination complex) with the target functional group. In other examples, the cerium species can form ionic bonds with the target functional group. In yet further examples, the cerium species can be freely dispersed within the polymer network. In the example shown in scheme (2), the cerium species (black trapezoid) and the counterion of the cerium-containing chemical species (gray trapezoid) are freely dispersed within the functional polymer network. As a result, the cerium species and the functional group are incorporated into the polymer network at extended intervals, where the pre-polymer molecules are joined together. Some examples of suitable cerium-containing chemical agents include cerium trichloride, cerium sulfate, cerium nitrate hexahydrate, cerium carbonate, cerium acetate, cerium ammonium nitrate, cerium(III) methanesulfonate (Ce(CH₃SO₃)₃), and cerium(III) trifluoromethanesulfonate (Ce(CF₃SO₃)₃).

The polymer can be additionally or alternatively functionalized after polymerization. Scheme (3) shows an example of post-polymerization functionalization. For example, a bifunctional reactive molecule containing the target functional group can be linked to a synthesized polymer. A cerium-containing chemical agent can also be added to incorporate a cerium species into the synthesized polymer. In some such examples, the functional groups are bound to a substrate-facing surface of the polymer layer. For example, the functional groups can be bound to a substrate-facing surface of the first polymer layer 202 of FIGS. 2A-2B. Again, as described above, the functional groups can act as complexing ligands to incorporate cerium species into the polymer layer. In other examples, the cerium species can be ionically or covalently bonded to the functional groups. In yet another example, the cerium species can be freely dispersed in the substrate-facing surface of polymer layer. In the example shown in scheme (3), the dotted lines represent a bond between the functional group of the bifunctional reactive molecules and the cerium species (black trapezoid). The counterion (gray trapezoid) of the cerium-containing chemical agent (e.g. a cerium salt) is freely dispersed within the functional polymer network in this example. As a more specific example, a polyvinylidene fluoride (PVDF) porous layer or other suitable layer may be functionalized with a chelating agent such as poly(acrylic acid) to complex cerium species. The PVDF porous layer may be used either for a first layer or second layer in the example of FIGS. 2A-2B.

In some examples, the first polymer layer 202 of FIGS. 2A-2B is functionalized and the second polymer layer 204 is not functionalized. Similarly, in some examples, the first polymer layer 202 of FIGS. 2A-2B may comprise a cerium species and the second polymer layer 204 may not comprise a cerium species. This can result in cost savings and faster and/or more efficient manufacturing than functionalizing the entire pad. In other examples, as described above, two or more surfaces of the pad can contain a cerium species and optionally a functional group, which can additionally or alternatively include one or more surfaces of the first polymer layer 202 and the second polymer layer 204. It will also be appreciated that the first polymer layer and/or the second polymer layer may comprise different cerium species and optionally different functional groups.

In some examples, the polymer may be functionalized by coating, in which the functional groups are not cross-linked to the polymer substrate, but instead adsorbed to the polymer substrate. For example, the polymer may be functionalized by incorporating reactive molecules containing the functional groups using a suitable solvent system. The solvent system can, in some examples, cause swelling of the polymer layer that allows the functional groups to be incorporated into at least a portion of a bulk volume of the polymer layer. A cerium species can be incorporated similarly, such as by including a cerium-containing chemical agent with the functional group in the solvent system used to swell the polymer layer.

Additionally, where functionalized polymers are used for the pads, the functionalization may be regenerated, for example, by adding new cerium species and optionally functional groups in-situ (e.g. through the planarization solution dispensing mechanism) to regenerate the functional groups. Additional aspects of regenerating the functionalization are described in more detail in U.S. patent application Ser. No. 17/729,805 entitled PAD SURFACE REGENERATION AND METAL RECOVERY, filed on Apr. 26, 2022, the entire contents of which are hereby incorporated by reference for all purposes. In such examples, cerium species can be included in the planarization solution, both to facilitate planarization and to help regenerate the pad. Examples of cerium species that can be included within the planarization solution include cerium (III) and cerium (IV) salts and/or organometallics that are soluble in a solvent system utilized by the planarization solution.

As introduced above, the methods disclosed herein can be used to additionally or alternatively incorporate a cerium species (e.g., an ion (e.g. as a salt or an organometallic complex) of Ce(III) or Ce(IV)) into the pad. Without wishing to be bound by theory, such cerium species can be bonded to the polymer matrix and/or to reactive units within the polymer layer. For example, a cerium species can be complexed by a hydroxyl, carbonyl, sulfonyl, sulfonate, and/or carboxylic acid functional group present within the polymer matrix. One or more cerium species can be additionally or alternatively dispersed freely in the polymer matrix. One or more cerium species can additionally or alternatively be ionically or covalently bonded to the functional groups within the polymer matrix. In some examples, as introduced above, the pad comprises a single layer. It will also be appreciated that, when the pad comprises a plurality of layers, the cerium species can be incorporated into one or more of the plurality of layers. The pad containing the cerium species can be formed in any suitable manner. In some examples, a cerium-containing chemical agent is blended into a pre-polymer, which is then polymerized to form a polymer pad, as described with regard to scheme (2) of FIG. 5 above. Any suitable cerium-containing chemical agents can be used. Some examples of suitable cerium-containing chemical agents include cerium trichloride, cerium sulfate, cerium nitrate hexahydrate, cerium carbonate, cerium acetate, cerium ammonium nitrate, cerium(III) methanesulfonate (Ce(CH₃SO₃)₃), and cerium(III) trifluoromethanesulfonate (Ce(CF₃SO₃)₃).

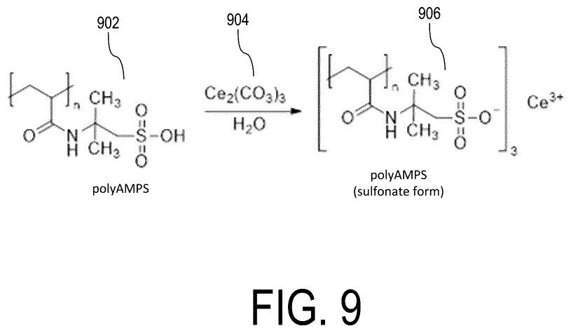

An example reaction scheme for the incorporation of cerium species into a polymer matrix is shown in FIG. 9. The polymer matrix can comprise polyAMPS, for example, shown at 902. PolyAMPS is a water-soluble commercially available polymer which comprises a hydrophobic backbone. At 904, polyAMPS is reacted with cerium carbonate in the presence of water to incorporate a cerium species. The sulfonic acid moiety of the polyAMPS becomes deprotonated and forms a poly(2-acrylamido-2-methyl-1-propanesulfonate) complex with a Ce(III) ion, as shown at 906, thereby incorporating the cerium species into the polymer matrix. A combination of polyAMPS and cerium can also be used for the planarization of polysilicon and silicon dioxide films, as described in further detail below.

The reaction scheme described in FIG. 9 can be applied to other sulfonic acid polymers and polymers comprising similar reactivity, such as polymers comprising sulfonyl groups. In some examples, a polymer matrix of a pre-existing polymer pad can comprise a sulfonyl group. A cerium species can be incorporated into the existing polymer pad in a similar scheme as that described in FIG. 9. The cerium species can be incorporated during a final stage of pad formation, or during an intermediate pre-polymer stage of the pad formation, such as the pre-polymer stage described above.

A concentration and density of the cerium species within the pad can be tailored at a level of the polymer matrix of the polymer pad, at the pre-polymer level, or at a curative/chain extending level of polymer synthesis to obtain suitable planarization or material removal rates and selectivity. This enables non-abrasive planarization of non-metal materials, and in-situ planarization of film stacks comprising such materials. For example, the pad containing the cerium species can be used to planarize oxides of silicon in the presence of an aqueous solution, which can include one or more additives, such as those used in cerium-oxide-particle-containing dispersions.

A pad containing a cerium species can be used to planarize a native oxide film on a surface of a substrate. For example, polysilicon films form a native silicon oxide layer upon exposure to air. However, the pad containing the cerium species can be used to planarize the native oxide. A planarization solution comprising another chemical species can be flowed onto the substrate to chemically planarize the polysilicon film underneath the oxide layer. For example, the underlying polysilicon film can be planarized at a rate of 500-600 nm/min using an aqueous solution of PDADMAC at pH 10. It will also be appreciated that other planarizing agents can be used. Other examples of suitable planarizing agents include polyAMPS, poly(dimethylamine-co-epichlorohydrin-co-ethylenediamine), poly(allylamine), poly(ethylene imine), poly(acrylamide) (PAA), and combinations thereof. Poly(dimethylamine-co-epichlorohydrin-co-ethylenediamine), poly(allylamine), and poly(ethylene imine), can planarize polysilicon films at similar rates to PDADMAC. An aqueous solution comprising a copolymer of PAA and PDADMAC has a lower planarizing rate than that obtained with PDADMAC but higher than that obtained with PAA. Such solutions may not poison the cerium species contained within the pad. This enables such solutions to be used in combination with a cerium-containing pad. Additional aspects of planarization are described in more detail in U.S. patent application Ser. No. 15/931,556 entitled CHEMICAL PLANARIZATION, filed on May 13, 2020, U.S. patent application Ser. No. 18/149,005 entitled CHEMICAL PLANARIZATION, filed on Dec. 30, 2022, U.S. patent application Ser. No. 17/729,805 entitled PAD SURFACE REGENERATION AND METAL RECOVERY, filed on Apr. 26, 2022, U.S. patent application Ser. No. 17/823,857 entitled TOOLS FOR CHEMICAL PLANARIZATION, filed on Aug. 31, 2022, and U.S. Provisional Application No. 63/504,098 entitled TOOLS FOR CHEMICAL PLANARIZATION, filed on May 24, 2023, the entire contents of which are hereby incorporated by reference for all purposes.

As a more specific example, a planarization solution comprising polyAMPS can be flowed onto the substrate to chemically planarize the polysilicon substrate. The pad containing the cerium species can be used to chemically planarize oxides of silicon from a polysilicon surface, and the polyAMPS can planarize the polysilicon surface below. The combined action of the cerium species and polyAMPS may achieve planarization of a substrate having, for example, both polysilicon and silicon oxide, with the use of one pad.

In other examples, two or more different chemical species can be contained within a planarization pad. For example, the pad can include a cerium species configured to remove silicon oxide and another chemical species configured to planarize polysilicon. In this manner, one pad can be used to remove a native oxide layer and to chemically planarize a substrate.

In some examples, a planarization pad comprising a cerium species can be used for abrasive-free planarization of patterned features with a combination of metallic and non-metallic layers. For example, cerium-containing salts of sulfonic acids, carboxylic acids, and/or diamines can be incorporated into a polymer pad. The sulfonic acids, carboxylic acids, and/or diamines can serve as active functionalities for chemical planarization of metals and refractory metals (e.g., barrier layers), and the cerium species can be an active site for removal of oxide or nitride materials (e.g., silicon oxide, silicon nitride, silicon oxynitride, or silicon oxycarbide) from a substrate.

In yet other examples, a chemical planarization process can utilize two or more separate planarization pads. For example, a first planarization pad can be used to remove a native oxide layer from a substrate. A second planarization pad can then be used to polish the substrate after the native oxide layer is removed. In some such examples, a substrate can be cycled from a first processing station pad within a processing tool that comprises the first planarization pad to a second processing station within the processing tool that comprises the second planarization pad.

In some examples, a pad containing a cerium species can additionally or alternatively be used to polish other materials. Other examples of suitable materials that can be polished by a pad containing a cerium species include silicon nitride, silicon oxynitride, and silicon carbonitride. Incorporating cerium species into the planarization pad can planarize such materials without using ceria or any other abrasives in a planarization medium.

One or more of these materials (e.g., silicon nitride, silicon oxynitride, or silicon carbonitride) can be used as stop barriers in shallow trench isolation (STI) and other related structures. In some instances, hot phosphoric acid is used to remove nitride films. However, incorporating cerium species into a planarization pad can planarize such nitride films without the use of ceria or any other abrasives, or acid.

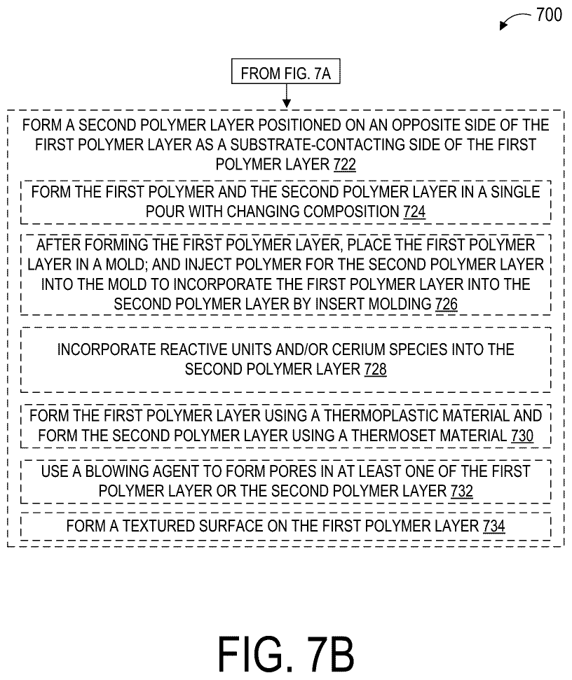

FIGS. 7A-7B show a flow diagram depicting an example method 700 of forming a pad for performing abrasive-free chemical planarization of a substrate. The following description of the method 700 is provided with reference to FIGS. 1-6 above. It will be appreciated that the method 700 also can be performed in other contexts.

At 702, the method 700 comprises forming a pad for performing abrasive-free chemical planarization of a substrate. The pad comprises a polymer layer comprising cerium species and optionally functional groups incorporated in a polymer layer, the functional groups comprising one or more of a complexing agent and a hydrolyzing agent. The functional groups alternatively or additionally can covalently or ionically bond, or otherwise complex with, the cerium species. For example, a pad can be formed that includes Ce(III) or Ce(IV) complexed by the functional groups. FIGS. 2A-2B show an example of a pad 200 that can be formed by the method 700 of FIGS. 7A-7B.

The pad may be formed in any suitable manner. In some examples, at 704, forming the pad comprises reacting a plurality of reactive units with a plurality of monomer units in the presence of a cerium-containing chemical agent, one or more of the plurality of reactive units or the plurality of monomer units comprising the functional groups. FIG. 6 illustrates some examples of suitable monomers. In scheme (1) of FIG. 5, polymerization of a monomer with a cerium-containing chemical agent comprising a cerium species and a bifunctional reactive molecule comprising a target functional group results in distribution of the cerium species and the target functional group throughout the polymer. Examples of cerium-containing chemical agents include cerium trichloride, cerium sulfate, cerium carbonate, cerium acetate, cerium nitrate hexahydrate, cerium ammonium nitrate, cerium(III) methanesulfonate (Ce(CH₃SO₃)₃), and/or cerium(III) trifluoromethanesulfonate (Ce(CF₃SO₃)₃).

In other examples, at 706, forming the pad comprises reacting a plurality of reactive units with a plurality of oligomer segments in the presence of a cerium-containing chemical agent, one or more of the plurality of reactive units or the plurality of oligomer segments comprising the functional groups. For example, in scheme (2) illustrated in FIG. 5, a monomer is linked to a chain extender to form an extended pre-polymer molecule. The extended pre-polymer molecule is then polymerized in the presence of a bifunctional reactive molecule containing the target functional group to form a functionalized polymer. In such examples, a cerium-containing chemical agent can be mixed either at the pre-polymer formation stage or the functionalized polymer synthesis stage. Example cerium-containing chemical agents include cerium trichloride, cerium sulfate, cerium carbonate, cerium acetate, cerium nitrate hexahydrate, cerium ammonium nitrate, cerium(III) methanesulfonate (Ce(CH₃SO₃)₃), and/or cerium(III) trifluoromethanesulfonate (Ce(CF₃SO₃)₃) can be combined with a pre-polymer, such as the pre-polymer of FIG. 5. incorporating a cerium species. In this manner, the cerium species can be incorporated into the pad through the polymerization of the pre-polymer.

In some examples, at 708, forming the pad comprises casting the polymer layer using a pre-polymer comprising a cerium-containing chemical agent and curing the pre-polymer. For example, a pre-polymer comprising the cerium-containing chemical agent may be formed as described above with reference to FIG. 5. The pre-polymer comprising the cerium-containing chemical agent may be more viscous than a solution of monomer units and may therefore be easier to handle and pour into molds than the monomer units. This allows for straightforward and efficient casting processes, especially for complex or intricate shapes. Pre-polymers can be formulated with specific compositions and properties to control factors such as hardness, flexibility, elongation, and curing time. Pre-polymers can be designed to cure at ambient temperature or with minimal heat input, simplifying the casting process. This can enable the polymer to be cured at a lower temperature, reducing energy consumption and enabling casting in molds that are sensitive to heat. Furthermore, since pre-polymers can be manufactured in controlled conditions, the use of a pre-polymer can result in more homogenous batch-to-batch production than polymerization from scratch. Casting with pre-polymers also allows for precise metering and control of material usage. This minimizes material waste and contributes to cost-effectiveness in production.

At 710, in some examples, forming the pad comprises molding the polymer layer. For example, a pre-polymer can be molded as described above to form the polymer layer.

In some examples, at 712, forming the pad comprises reacting a surface of the polymer layer with the cerium-containing chemical agent and optionally with reactive units comprising the functional groups, depending for example upon whether the cerium species provided by the cerium containing chemical agent can bond or otherwise adsorb to the pad surface. Where a surface of the pad has a low affinity for adsorbing cerium, a functional group can be reacted with the pad surface, the functional group selected to complex or otherwise bond to cerium III and/or IV. Example functional groups include those described above. Alternatively or additionally, the functional group can be selected to perform one or more of hydrolysis or complexing of material from a surface being planarized.

At 714, in some examples, forming the pad comprises swelling the polymer layer with a solvent and then incorporating the cerium species and functional groups into at least a portion of a bulk volume of the polymer layer. For example, the polymer layer can be treated with a solvent system that causes swelling of the polymer layer. This enables the cerium species and functional groups to be incorporated into at least a portion of a bulk volume of the polymer layer. The cerium species may be incorporated by adding a cerium-containing chemical agent, as described above.

In some examples, at 716, forming the polymer layer comprises forming a polyurethane, wherein the functional groups are located on an isocyanate moiety or a polyol moiety of the polyurethane. For example, as described above with reference to FIG. 6, the functional groups can be located on an isocyanate, such as 4,4′-methylene bis(phenyl isocyanate), tolyene-2,4-diisocyanate, and hexamethyl diisocyanate. Reaction of a hydroxyl group or an amine group with the isocyanate can create the urethane linkage of the polymer backbone. In other examples, the functional groups are located on a polyol moiety of the polyurethane. For example, a polyol can be reacted with an isocyanate to form a polyurethane. In this manner, the functional groups can be integrated into the polyurethane. A cerium species may be incorporated by complexation with the functional groups. The cerium species can additionally or alternatively be ionically or covalently bonded to the functional groups, or can be freely dispersed within the polymer layer.

In some examples, at 718, forming the polymer layer comprises forming a polyanhydride, wherein the functional groups are located on an anhydride moiety or a polyol moiety of the polyanhydride. For example, as described above with reference to FIG. 6, the functional groups can be located on an anhydride, such as pyromellitic dianhydride, ethylenediaminetetraacetic dianhydride, and diethylenetriaminepentaacetic dianhydride. In this manner, the functional groups can be incorporated into a polyanhydride. As another example, polyols can be incorporated into polyanhydride-based systems as additives or modifiers. A cerium species may be incorporated by complexation with the functional groups. The cerium species can additionally or alternatively be ionically or covalently bonded to the functional groups, or can be freely dispersed within the polymer layer.

In some examples, at 720, forming the polymer layer comprises forming an epoxy, wherein the functional groups are located on an epoxide moiety of the epoxy. For example, as described above with reference to FIG. 6, the functional groups can be located on an epoxy. Cross-linking of the epoxies thereby results in formation of a polymer containing the functional groups. In other examples, the functional groups are located on a polyol bound within an epoxy chain. The polyol can serve as the curing agent or an additive/modifier. Polymerization thereby incorporates the polyol and the functional groups into the polymer matrix. A cerium species may be incorporated by complexation with the functional groups. The cerium species can additionally or alternatively be ionically or covalently bonded to the functional groups, or can be freely dispersed within the polymer layer.

Referring now to FIG. 7B, in some examples, at 722, the method 700 further comprises forming a second polymer layer positioned on an opposite side of the first polymer layer as a substrate-contacting side of the first polymer layer. In some examples, the first polymer layer 202 and the second polymer layer 204 are integrally constructed as a bilayer during a single process. In some such examples, the first polymer layer 202 and the second polymer layer 204 are formed by liquid casting, injection molding, extrusion, additive manufacturing, or a combination thereof.

In some examples, at 724, forming the first polymer and the second polymer layer comprises forming the first polymer and the second polymer layer in a single pour with changing composition. For example, a composition of a liquid poured into a mold during a liquid casting process can be changed partway through the liquid casting process. This results in an integral structure having two distinct layers produced during a single process, which enables the composition and other properties of the porous pad to be tuned during manufacturing. The use of a single process to form both layers also reduces cost and increases process efficiency relative to forming each layer separately.

In other examples, the first polymer layer 202 and the second polymer layer 204 are fabricated in separate steps. In some such examples, the first polymer layer 202 and the second polymer layer 204 are formed by liquid casting, injection molding, extrusion, additive manufacturing, or a combination thereof.

In some examples, at 726, the method 700 further comprises, after forming the first polymer layer, placing the first polymer layer in a mold. The method 700 further comprises injecting polymer for the second polymer layer into the mold to incorporate the first polymer layer into the second polymer layer by insert molding. This enables inspection of the first layer before forming the second layer and can allow for finer control over the formation of the first layer and the second layer. In some examples, it can be faster, cheaper, and/or more efficient to fabricate the first layer and the second layer separately than in a single step as described above.

At 728, in some examples, the method 700 comprises incorporating a second plurality of reactive units and/or cerium species within polymer chains of the second polymer layer. For example, the cerium species and optionally functional groups can be incorporated into the second polymer layer 204 of FIGS. 2A-2B in the manners described above.

In some examples, at 730, forming the first polymer layer comprises forming the first polymer layer using a thermoplastic material, and forming the second polymer layer comprises forming the second polymer layer using a thermoset material. For example, the first polymer layer 202 of FIGS. 2A-2B may comprise a thermoplastic material and the second polymer layer 204 may comprise a thermoset material, or vice versa. This enables each layer to have a tunable molecular structure and physical characteristics (e.g., compressibility and toughness).

At 732, in some examples, the method 700 comprises using a blowing agent to form pores in at least one of the first polymer layer or the second polymer layer. This enables formation of a porous polymer structure, which can have a larger surface area (including surfaces of the pores) and greater compressibility than a solid polymer.

In some examples, at 734, the method 700 comprises forming a textured surface on the first polymer layer. For example, the pad 400 of FIG. 4 comprises a textured substrate-facing surface 406. The textured surface can accelerate removal of material from a substrate and increases surface area relative to a smooth substrate-facing surface.

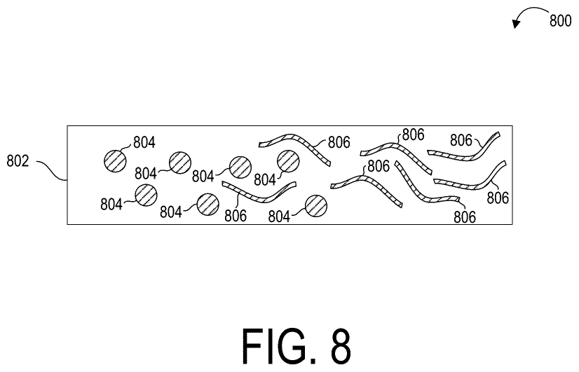

FIG. 8 shows a schematic view of another example pad 800 that is suitable for use as the pad 104 of FIG. 1. The pad 800 comprises a single polymer layer 802. However, as described above, in other examples, the pad 800 may comprise any other suitable number of layers (e.g., two or more layers). The pad 800 comprises a plurality of microspheres 804 and/or a plurality of fillers 806. The microspheres 804 and/or the fillers 806 are dispersed through the polymer layer 802 during pad manufacturing. The microspheres 804 and the fillers 806 each comprise a polymer, cerium species, and optionally functional groups (e.g., the cerium species and functional groups described above with reference to FIGS. 5-6) incorporated within the polymer. However, the microspheres 804 and the fillers 806 are not covalently bonded to the polymer layer 802 of the pad 800. Instead, the microspheres 804 and the fillers 806 can be held within the polymer layer 802 by electrostatic forces, hydrophilic/hydrophobic interactions, Van der Waals forces, mechanical interlocking, etc. Furthermore, the microspheres 804 and the fillers 806 can be regenerated chemically. This enables repeated use of the cerium species and optionally functional groups for multiple wafers.

]This disclosure is presented by way of example and with reference to the associated drawing figures. Components, process steps, and other elements that can be substantially the same in one or more of the figures are identified coordinately and are described with minimal repetition. It will be noted, however, that elements identified coordinately can also differ to some degree. It will be further noted that some figures can be schematic and not drawn to scale. The various drawing scales, aspect ratios, and numbers of components shown in the figures can be purposely distorted to make certain features or relationships easier to see.

“And/or” as used herein is defined as the inclusive or V, as specified by the following truth table:

| A | B | A ∨ B |
|---|---|---|
| True | True | True |
| True | False | True |
| False | True | True |
| False | False | False |

The terminology “one or more of A or B” as used herein comprises A, B, or a combination of A and B. The terminology “one or more of A, B, or C” is equivalent to A, B, and/or C. As such, “one or more of A, B, or C” as used herein comprises A individually, B individually, C individually, a combination of A and B, a combination of A and C, a combination of B and C, or a combination of A, B and C.

It will be understood that the configurations and/or approaches described herein are example in nature, and that these specific embodiments or examples are not to be considered in a limiting sense, because numerous variations are possible. The specific routines or methods described herein can represent one or more of any number of strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A pad for performing abrasive-free chemical planarization of a non-metallic material, the pad comprising:
a polymer layer configured to contact a substrate during the abrasive-free chemical planarization, wherein the polymer layer comprises a cerium species, the cerium species comprising one or more of Ce(III) or Ce(IV).

2. The pad of claim 1, wherein the cerium species is incorporated as one or more of cerium trichloride, cerium sulfate, cerium carbonate, cerium nitrate hexahydrate, cerium acetate, cerium ammonium nitrate, cerium (III) methanesulfonate, or cerium (III) trifluoromethanesulfonate.

3. The pad of claim 2, wherein the cerium-containing is incorporated as one or more organometallic complexes of Ce(III) or Ce(IV).

4. The pad of claim 1, wherein the polymer layer further comprises a functional group comprising one or more of a complexing agent or a hydrolyzing agent incorporated into a polymer matrix within the polymer layer.

5. The pad of claim 1, wherein the polymer layer comprises the cerium species dispersed freely in a polymer matrix of the polymer layer.

6. The pad of claim 4, wherein the polymer layer comprises the cerium species ionically or covalently bonded to the functional group.

7. The pad of claim 4, wherein the polymer layer comprises the cerium species complexed to the functional group.

8. The pad of claim 4, wherein the functional group comprises one or more of a hydroxyl, a carbonyl, a sulfonyl, or a carboxylic acid functional group.

9. The pad of claim 1, further comprising a plurality of polymer layers, wherein the cerium species is incorporated into two or more polymer layers of the plurality of polymer layers.

10. A chemical planarization tool, comprising
a pad for performing abrasive-free chemical planarization of a non-metallic material, the pad comprising a polymer layer configured to contact a substrate during the abrasive-free chemical planarization, wherein the polymer layer comprises a cerium species, the cerium species comprising one or more of Ce(III) or Ce(IV),
a platen supporting the pad,
a substrate holder configured to hold a substrate against the surface of the pad, and
a planarization solution introduction system for introducing a planarization solution onto the pad.

11. The tool of claim 10, further comprising the planarization solution in the planarization solution introduction system, wherein the planarization solution comprises poly(2-acrylamido-2-methyl-1-propanesulfonic acid).

12. A method, comprising:
forming a pad for performing abrasive-free chemical planarization of a substrate, the pad comprising a polymer layer comprising a cerium species, the cerium species comprising one or more of Ce(III) or Ce(IV).

13. The method of claim 12, wherein forming the pad comprises combining a cerium-containing chemical agent and a pre-polymer and polymerizing the pre-polymer to form the polymer layer comprising the cerium species.

14. The method of claim 13, wherein the cerium-containing chemical agent comprises one or more of cerium trichloride, cerium carbonate, cerium acetate, cerium sulfate, cerium nitrate hexahydrate, cerium ammonium nitrate, cerium(III) methanesulfonate, or cerium(III) trifluoromethanesulfonate.

15. The method of claim 13, wherein the cerium-containing chemical agent comprises one or more organometallic complexes of Ce(III) or Ce(IV).

16. The method of claim 13, wherein forming the pad comprises reacting a plurality of reactive units with a plurality of monomer units in the presence of the cerium-containing chemical agent, wherein one or more of the plurality of reactive units or the plurality of monomer units comprises functional groups.

17. The method of claim 13, wherein forming the pad comprises reacting a plurality of reactive units with a plurality of oligomer segments in the presence of the cerium-containing chemical agent, wherein one or more of the plurality of reactive units or the plurality of oligomer segments comprises functional groups.

18. The method of claim 13, wherein forming the pad comprises reacting a surface of the polymer layer with the cerium-containing chemical agent and with reactive units comprising functional groups.

19. The method of claim 12, wherein forming the pad comprises swelling the polymer layer with a solvent, and incorporating the cerium species and reactive units comprising functional groups into at least a portion of a bulk volume of the polymer layer.

20. The method of claim 12, further comprising forming a second polymer layer positioned on an opposite side of the polymer layer comprising the cerium species as a substrate-contacting side of the polymer layer comprising the cerium species, further comprising incorporating a second plurality of cerium species and/or reactive units comprising functional groups within polymer chains of the second polymer layer.
